(19) United States
(12) Patent Application Publication
(10) Pub. No.: US 2026/0324217 A1
(43) Pub. Date: Oct. 15, 2026

(54) DISPLAY PANEL AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Kening ZHENG, Beijing (CN); Tong WU, Beijing (CN); Mingkun YANG, Beijing (CN); Changlin LIU, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 19/146,532

(22) PCT Filed: Aug. 23, 2024
(86) PCT No.: PCT/CN2024/114374

§ 371 Date: Jul. 9, 2025

(30) Foreign Application Priority Data
Mar. 26, 2024 (CN) 202410354562.X

(51) Int. Cl. H10K 59/131; H10K 59/122

(52) U.S. Cl. CPC H10K 59/131; H10K 59/122

(57) ABSTRACT

The invention discloses a display panel and a display device, and relates to the technical field of display. A plurality of first cathode patterns in a third cathode layer of the display panel are arranged at intervals, so that the plurality of first cathode patterns do not cover a second display area in the whole layer. Compared with the cathode layer covering the whole second display area, the influence on the light transmittance can be effectively reduced, and the imaging effect of the camera located in the second display area is good.

### CROSS-REFERENCE TO RELATED APPLICATIONS

This application is a national phase entry under 35 USC 371 of International Patent Application No. PCT/CN2024/114374, filed on Aug. 23, 2024, which claims priority to Chinese Patent Application No. 202410354562.X, filed on Mar. 26, 2024, each are incorporated herein by reference in their entirety.

### TECHNICAL FIELD

The present disclosure relates to the field of display technologies, and in particular, to a display panel and a display apparatus.

### BACKGROUND

Organic light-emitting diodes (OLEDs) have been widely used in the display field due to self-luminescence, low driving voltage, high luminous efficiency, fast response speed, flexible display and other advantages.

The power consumption of OLEDs need to be further optimized.

### SUMMARY

In an aspect, a display panel is provided. The display panel has a plurality of sub-pixels, and the display panel includes a substrate, a light-emitting device layer and a plurality of connection portions. The substrate is provided with a circuit layer therein. The light-emitting device layer is disposed on a side of the substrate, and the light-emitting device layer includes a cathode layer and an anode layer that are disposed opposite to each other, and a light-emitting layer disposed between the cathode layer and the anode layer. The cathode layer is farther away from the substrate than the anode layer. The cathode layer includes a plurality of cathodes separate from one another; and a cathode corresponds to at least one sub-pixel. The connection portions are disposed on the side of the substrate. In a direction parallel to a plane where the substrate is located, a connection portion is located on at least one side of the cathode; and the cathode is connected to the circuit layer by the connection portion.

In some embodiments, at least one connection portion in the plurality of connection portions is a first connection portion, and the first connection portion includes a first connection column. The first connection column is disposed on the side of the substrate. The cathode is connected to the first connection column, and the first connection column is connected to the circuit layer.

In some embodiments, the first connection column includes a first end away from the substrate and a second end proximate to the substrate, and an orthographic projection of the first end on the substrate is located within an orthographic projection of the second end on the substrate.

In some embodiments, at least one connection portion in the plurality of connection portions is a second connection portion, and the second connection portion includes a second connection column group and a first connection sub-portion. The second connection column group includes at least one second connection column and disposed on the side of the substrate. The first connection sub-portion is disposed on a side of the second connection column proximate to the substrate. The cathode is connected to at least one of the second connection column group and the first connection sub-portion, and the second connection portion is connected to the circuit layer.

In some embodiments, the second connection column includes a third end away from the substrate and a fourth end proximate to the substrate. In a case where the cathode is connected to the second connection column group, the second connection column group is connected to the first connection sub-portion, and an orthographic projection of a third end of a second connection column in the second connection column group connected to the cathode on the substrate is located within an orthographic projection of a fourth end thereof on the substrate. In a case where the cathode is connected to the first connection sub-portion, an orthographic projection of a fourth end of a second connection column on the substrate is located within an orthographic projection of a third end thereof on the substrate.

In some embodiments, an orthographic projection of a second connection column closest to the cathode on the substrate is located within an orthographic projection of the first connection sub-portion on the substrate.

In some embodiments, the display panel comprises a plurality of pixels, each pixel includes at least three sub-pixels, and each sub-pixel has a separate cathode. The connection portions include a first connection portion and/or a second connection portion; a connection portion connected to a cathode of at least one sub-pixel is the first connection portion, and/or a connection portion connected to a cathode of at least one sub-pixel is the second connection portion.

In some embodiments, the circuit layer includes a first signal line, a second signal line and a third signal line; and the pixel includes at least a first sub-pixel, a second sub-pixel and a third sub-pixel. A connection portion connected to a cathode of the first sub-pixel is connected to the first signal line; a connection portion connected to a cathode of the second sub-pixel is connected to the second signal line; and a connection portion connected to a cathode of the third sub-pixel is connected to the third signal line.

In some embodiments, the pixel further includes a fourth sub-pixel, and the fourth sub-pixel and one of the first sub-pixel, the second sub-pixel and the third sub-pixel are configured to emit light of a same color. A connection portion connected to a cathode of the fourth sub-pixel and a connection portion connected to a cathode of the sub-pixel configured to emit light of the same color as the fourth sub-pixel are connected to a same signal line.

In some embodiments, the anode layer includes a plurality of anodes. The circuit layer further includes a plurality of pixel circuits, and an anode is connected to a pixel circuit. The pixel circuit is not in contact with the first signal line, the second signal line and the third signal line.

In some embodiments, in a same pixel, sub-pixels for emitting lights of different colors are connected to different signal lines; and/or in different pixels, sub-pixels for emitting light of a same color are connected to a same signal line.

In some embodiments, the display panel further includes a partition portion. In the direction parallel to the plane where the substrate is located, the partition portion and the connection portion are located on a same side of the cathode connected to the connection portion. An orthographic projection of the partition portion on the substrate does not overlap with the orthographic projection of the connection portion on the substrate.

In some embodiments, a distance between the partition portion and the cathode is greater than or equal to 2 μm.

In some embodiments, two adjacent cathodes in the plurality of cathodes are a first cathode and a second cathode. In the direction parallel to the plane where the substrate is located, the first cathode is located on a side of the second cathode. The connection portion is connected to the first cathode, and the partition portion is connected to the second cathode.

In some embodiments, the light-emitting device layer includes a plurality of light-emitting devices, and a sub-pixel includes a light-emitting device. The display panel further includes a pixel defining layer. The pixel defining layer is disposed on the side of the substrate. The pixel defining layer includes a plurality of pixel openings and a pixel defining main body. The light-emitting device of the sub-pixel is disposed corresponding to a pixel opening, and the connection portion penetrates through the pixel defining main body to be connected to the circuit layer.

In some embodiments, the anode layer includes a plurality of anodes, the light-emitting layer includes a plurality of light-emitting sub-layers, and the light-emitting device includes the cathode and an anode, and a light-emitting sub-layer located between the cathode and the anode. The plurality of sub-pixels include a red sub-pixel, a green sub-pixel and a blue sub-pixel; and an area of an orthographic projection of a light-emitting sub-layer of the blue sub-pixel on the substrate is greater than an area of an orthographic projection of a light-emitting sub-layer of the red sub-pixel on the substrate and an area of an orthographic projection of a light-emitting sub-layer of the green sub-pixel on the substrate.

In some embodiments, the display panel further includes an isolation layer. The isolation layer is disposed on a side of the pixel defining layer away from the substrate. The isolation layer includes a plurality of isolation openings, the plurality of isolation openings correspond to the plurality of pixel openings, and a dimension of an isolation opening is smaller than a dimension of the pixel opening corresponding to the isolation opening.

In some embodiments, the cathode corresponds to a single sub-pixel; or the cathode corresponds to multiple sub-pixels for emitting light of a same color.

In another aspect, a display apparatus is provided. The display apparatus includes the display panel as described in any of the above embodiments.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1 is a structural diagram of a display apparatus, in accordance with some embodiments of the present disclosure;

FIG. 2 is a structural diagram of a display panel, in accordance with some embodiments of the present disclosure;

FIG. 3 is an enlarged view of an area S of the display panel shown in FIG. 2;

FIG. 4 is a structural diagram of a display panel, in accordance with some embodiments of the present disclosure;

FIG. 5 is a cross-sectional view taken along a section line A1-A2 in FIG. 4;

FIG. 6 is a diagram showing a relationship between luminance and voltage of a sub-pixel;

FIG. 7 is a structural diagram of another display panel, in accordance with some embodiments of the present disclosure;

FIG. 8 is a structural diagram of another display panel, in accordance with some embodiments of the present disclosure;

FIG. 9A is an enlarged view of an area B in FIG. 8;

FIG. 9B is an enlarged view of an area C in FIG. 8;

FIG. 9C is an enlarged view of an area D in FIG. 8;

FIG. 10 is a structural diagram of another display panel, in accordance with some embodiments of the present disclosure;

FIG. 11 is a structural diagram of another display panel, in accordance with some embodiments of the present disclosure;

FIG. 12 is a top view of a structure of an isolation layer and a pixel defining layer, in accordance with some embodiments of the present disclosure;

FIG. 13 is a flow diagram of a method for manufacturing a display panel, in accordance with some embodiments of the present disclosure; and

FIGS. 14A to 14N are structural diagrams in steps of a method for manufacturing a display panel, in accordance with some embodiments of the present disclosure.

### DETAILED DESCRIPTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” is construed as open and inclusive, i.e., “including, but not limited to”. In the description of the specification, the terms such as “one embodiment”, “some embodiments”, “exemplary embodiments”, “example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

In the description of some embodiments, the expressions “coupled” and “connected” and derivatives thereof may be used. The term “connection” should be understood in a broad sense. For example, the “connection” may be a fixed connection, a detachable connection, or of an integrated structure; it may be a direct connection or an indirect connection by an intermediate medium. The term “coupled” indicates, for example, that two or more components are in direct physical or electrical contact. However, the term “coupled” or “communicatively coupled” may also mean that two or more components are not in direct contact with each other, but still cooperate or interact with each other. The embodiments disclosed herein are not necessarily limited to the content herein.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The phrase “applicable to” or “configured to” as used herein indicates an open and inclusive expression, which does not exclude apparatuses that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or values exceeding those stated.

The term “about”, “substantially” or “approximately” as used herein includes a stated value and an average value within an acceptable range of deviation of a particular value. The acceptable range of deviation is determined by a person of ordinary skill in the art in consideration of the measurement in question and errors associated with the measurement of a particular quantity (i.e., limitations of the measurement system).

The term such as “parallel”, “perpendicular” or “equal” as used herein includes a stated condition and a condition similar to the stated condition. A range of the similar condition is within an acceptable range of deviation. The acceptable range of deviation is determined by a person of ordinary skill in the art in view of measurement in question and errors associated with the measurement of a particular quantity (i.e., limitations of the measurement system). For example, the term “parallel” includes absolute parallelism and approximate parallelism, and an acceptable range of deviation of the approximate parallelism may be a deviation within 5°; the term “perpendicular” includes absolute perpendicularity and approximate perpendicularity, and an acceptable range of deviation of the approximate perpendicularity may also be a deviation within 5°; and the term “equal” includes absolute equality and approximate equality, and an acceptable range of deviation of the approximate equality may be a difference between two equals being less than or equal to 5% of either of the two equals.

It will be understood that when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plane views as idealized exemplary drawings. In the accompanying drawings, thicknesses of layers and sizes of areas/regions are enlarged for clarity. Variations in shapes relative to the accompanying drawings due to, for example, manufacturing technologies and/or tolerances may be envisaged. Therefore, the exemplary embodiments should not be construed to be limited to the shapes of areas/regions shown herein, but to include deviations in the shapes due to, for example, manufacturing. For example, an etched area/region shown in a rectangular shape generally has a feature of being curved. Therefore, the areas/regions shown in the accompanying drawings are schematic in nature, and their shapes are not intended to show actual shapes of the areas/regions in an apparatus, and are not intended to limit the scope of the exemplary embodiments.

Embodiments of the present disclosure provide a display apparatus. The display apparatus is an electronic device having a function of displaying images (including a still image or a moving image, where the moving image may be a video). For example, the display apparatus may be any of, but is not limited to, a display, a television, a billboard, a digital photo frame, a laser printer with display function, a telephone, a mobile phone, a personal digital assistant (PDA), a digital camera, a portable camcorder, a viewfinder, a navigator, a large-area wall, a home appliance, an information query device (e.g., business query devices for e-government, banks, hospitals, electricity and other departments), a monitor, an electronic picture screen, a virtual reality (VR) display device, an augmented reality (AR) display device and a vehicle-mounted display.

In some examples, the display apparatus may be an electroluminescent display apparatus or a photoluminescent display apparatus. In a case where the display apparatus is the electroluminescent display apparatus, the electroluminescent display apparatus may be an organic light-emitting diode (OLED) display apparatus or a quantum dot light-emitting diode (QLED) display apparatus. In a case where the display apparatus is the photoluminescent display apparatus, the photoluminescent display apparatus may be a quantum dot photoluminescent display apparatus.

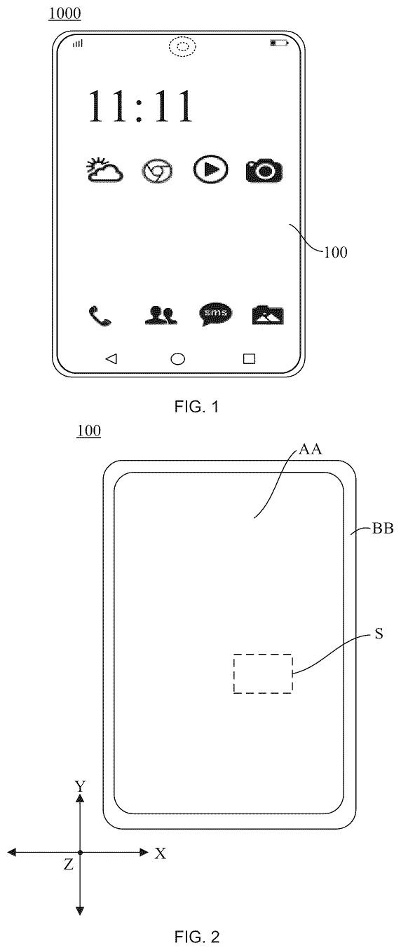

FIG. 1 is a structural diagram of a display apparatus in accordance with some embodiments of the present disclosure.

As shown in FIG. 1, the embodiments of the present disclosure will be exemplarily illustrated by considering an example in which the display apparatus 1000 is a mobile phone. The display apparatus 1000 includes a display panel 100. The display panel 100 may be any of an OLED display panel, a QLED display panel and a mini/micro LED display panel.

The embodiments of the present disclosure will be exemplarily illustrated by considering an example in which the display panel 100 is an OLED display panel, but the embodiments of the present disclosure include but are not limited thereto.

FIG. 2 is a structural diagram of a display panel in accordance with some embodiments of the present disclosure.

For facilitating description of the following contents, an XYZ coordinate system is established. The first direction X and the second direction Y are both parallel to a plane where a display surface of the display panel 100 is located, and the first direction X and the second direction Y intersect. For example, the first direction X and the second direction Y are perpendicular to each other. The third direction Z is perpendicular to the plane where the display surface of the display panel 100 is located.

Referring to FIG. 2, the display panel 100 may include a display area AA and a peripheral area BB. The display area AA is an area of the display panel 100 for displaying images, and the peripheral area BB is an area of the display panel 100 in addition to the display area AA. The peripheral area BB may be located on at least one side (e.g., one side or multiple sides) of the display area AA. For example, the peripheral area BB may be provided around the display area AA.

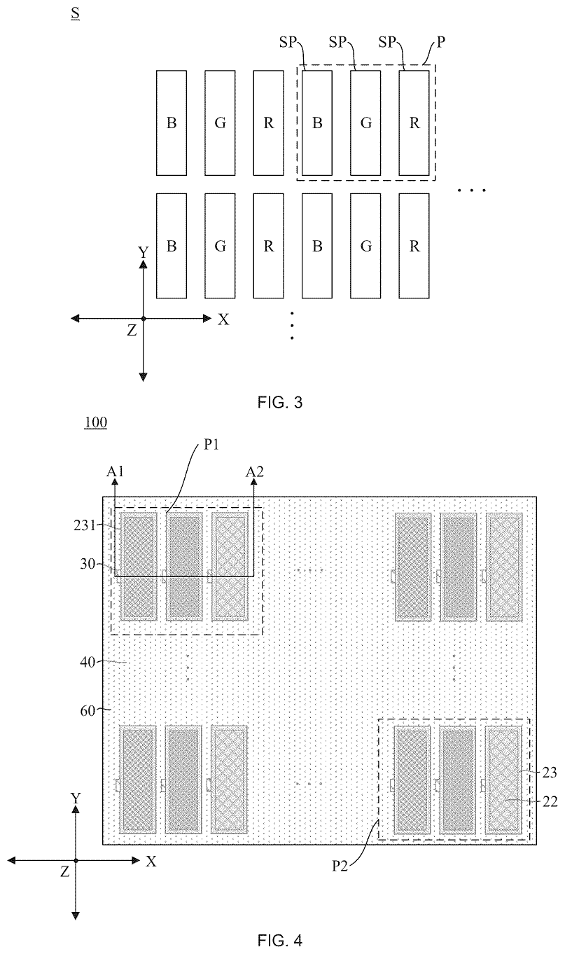

FIG. 3 is an enlarged view of an area S of the display panel shown in FIG. 2.

The display area AA is provided with a plurality of pixels P therein. In some examples, the first direction X is a row direction of the pixels P, and the second direction Y is a column direction of the pixels P. The peripheral area BB may include a cathode voltage signal bus.

Referring to FIG. 3, each pixel P includes at least three sub-pixels SP, where the sub-pixel SP is the minimum unit of the display panel 100 for displaying images. Each sub-pixel SP may emit light of a single color. For example, each pixel P includes at least a first sub-pixel, a second sub-pixel and a third sub-pixel, and of the first sub-pixel, the second sub-pixel and the third sub-pixel, any sub-pixel emits red light, one sub-pixel emits green light, and one sub-pixel emits blue light. For convenience of description below, the embodiment of the present disclosure is described by considering an example where the first sub-pixel is a red sub-pixel R, the second sub-pixel is a green sub-pixel G, and the third sub-pixel is a blue sub-pixel B. Of course, the first sub-pixel may also be a green sub-pixel or a blue sub-pixel, the second sub-pixel may also be a red sub-pixel or a blue sub-pixel, and the third sub-pixel may also be a red sub-pixel or a green sub-pixel, which is also applicable to the embodiments of the present disclosure.

There may be a plurality of arrangements of the sub-pixels SP in the pixel P. For example, the arrangement of the sub-pixels is a real RGB arrangement, and the pixel P includes a first sub-pixel, a second sub-pixel and a third sub-pixel. For example, with continued reference to FIG. 3, the third sub-pixels, the second sub-pixels and the first sub-pixels are arranged in an array in the first direction X. The rendering algorithm may adopt sub-pixel rendering (SPR). As another example, the arrangement of the sub-pixels SP is a GGRB arrangement, and the pixel P includes a first sub-pixel, a second sub-pixel, a third sub-pixel and a fourth sub-pixel, where the fourth sub-pixel is a green sub-pixel G, and both the fourth sub-pixel and the second sub-pixel emit green light. It will be noted that the arrangement of the sub-pixels SP in the pixel P also includes a pentile arrangement, a diamond arrangement or a delta arrangement, but is not limited thereto.

The sub-pixel SP includes a light-emitting device and a pixel circuit. The light-emitting device includes a cathode, an anode and a light-emitting sub-layer. The anode is connected to the pixel circuit, and the cathode is connected to the cathode voltage signal bus. The pixel circuit provides an anode voltage Vdd to the anode, and the cathode voltage signal bus provides a cathode voltage Vss to the cathode. A voltage difference between the anode voltage Vdd and the cathode voltage Vss is a voltage of the sub-pixel SP. Holes are injected into the light-emitting sub-layer through the anode and electrons are injected into the light-emitting sub-layer through the cathode, and the formed electrons and holes create excitons in the light-emitting sub-layer. Excitons transition back to a ground state through radiation, and the light-emitting device emits light. In this case, the sub-pixel SP emits light. By adjusting the voltage of the sub-pixel SP, the luminance of the light-emitting device may be adjusted to achieve display of multiple colors.

A structure of the display panel 100 will be described in detail below.

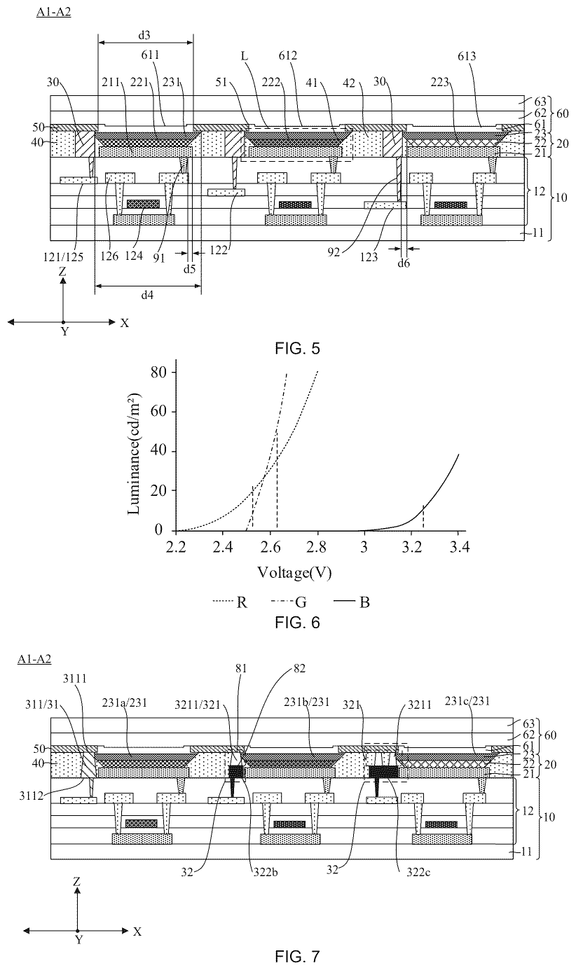

FIG. 4 is a structural diagram of a display panel in accordance with some embodiments of the present disclosure. FIG. 5 is a cross-sectional view taken along a section line A1-A2 in FIG. 4.

Referring to FIGS. 4 and 5, the display panel 100 includes a substrate 10 and a light-emitting device layer 20. The light-emitting device layer 20 is disposed on a side of the substrate 10. The first direction X and the second direction Y are parallel to a plane where the substrate 10 is located, and the third direction Z is perpendicular to the plane where the substrate 10 is located.

The substrate 10 is provided with a circuit layer 12 therein. The circuit layer 12 includes a plurality of pixel circuits. In some examples, the circuit layer 12 includes a thin film transistor (TFT) layer, the plurality of pixel circuits are disposed in the TFT layer, and the pixel circuit includes multiple TFTs. For example, the TFT layer includes an active layer (Active) formed using a patterning process, a gate insulating layer (GI) formed on the active layer by deposition and other processes, a gate of a thin film transistor formed on the gate insulating layer using a patterning process, a dielectric (inter-layer dielectric, ILD) layer formed on the gate by deposition and other methods, a source-drain metal layer formed on the dielectric layer, and a planarization layer (PLN) covering the source-drain metal layer and the exposed dielectric layer, where the source-drain metal layer forms a source and a drain of the thin film transistor, for example, the source is electrically connected to the active layer through a via hole in the dielectric layer. Here, the active layer may be made of a material such as polysilicon or metal oxide, the gate insulating layer may be made of an inorganic insulating material such as silicon oxide, silicon nitride or silicon oxynitride, and the dielectric layer may be made of an inorganic insulating material such as silicon oxide, silicon nitride or silicon oxynitride. The material of the gate includes a metal such as aluminum (Al), titanium (Ti) and cobalt (Co) or an alloy thereof. The planarization layer is made of, for example, an organic material, or may be made of an inorganic insulating material such as silicon oxide, silicon nitride or silicon oxynitride. The planarization layer has a planarization effect, which is beneficial to a quality of subsequent material deposition. As a result, a surface difference of an anode layer formed subsequently may be reduced, there is a relatively large amount of reflected light, and the luminous performance is good. In addition, the planarization layer is conducive to blocking moisture and oxygen from entering the light-emitting device of the sub-pixel from the bottom.

With continued reference to FIG. 5, the substrate 10 further includes a base substrate 11. The base substrate 11 is disposed on a side of the circuit layer 12 away from the light-emitting device layer 20, and plays a support role for other structures in the display panel 100. The base substrate 11 may be a rigid substrate, and a material of the rigid substrate may be glass or polymethyl methacrylate (PMMA). Alternatively, the base substrate 11 may be a flexible substrate, and a material of the flexible substrate may be polyethylene terephthalate (PET), polyethylene naphthalate two formic acid glycol ester (PEN), ultra-thin glass or polyimide (PI).

With continued reference to FIGS. 4 and 5, the light-emitting device layer 20 is disposed on a side of the substrate 10. For example, the light-emitting device layer 20 is disposed on a side of the circuit layer 12 away from the base substrate 11. The light-emitting device layer 20 includes a plurality of light-emitting devices L, where anodes of the plurality of light-emitting devices L form an anode layer 21, light-emitting sub-layers of the plurality of light-emitting devices L form a light-emitting layer 22, and cathodes of the plurality of light-emitting devices form a cathode layer 23. The anode layer 21 and the cathode layer 23 are provided opposite to each other, the light-emitting layer 22 is located between the anode layer 21 and the cathode layer 23, and the cathode layer 23 is farther away from the substrate 10 than the anode layer 21. That is to say, in a direction away from the substrate 10, the anode layer 21, the light-emitting layer 22 and the cathode layer 23 are stacked in sequence, and an anode, a light-emitting sub-layer and a cathode that are stacked constitute a light-emitting device L.

A plurality of light-emitting sub-layers may emit lights of different colors. For example, the plurality of light-emitting sub-layers include a first light-emitting sub-layer 221, a second light-emitting sub-layer 222 and a third light-emitting sub-layer 223, and of the first light-emitting sub-layer 221, the second light-emitting sub-layer 222 and the third light-emitting sub-layer 223, one light-emitting sub-layer emits red light, one light-emitting sub-layer emits green light, and one light-emitting sub-layer emits blue light. For convenience of description below, the embodiment of the present disclosure is described by considering an example where the first light-emitting sub-layer is a red light-emitting sub-layer, the second light-emitting sub-layer is a green light-emitting sub-layer, and the third light-emitting sub-layer is a blue light-emitting sub-layer. The red light-emitting sub-layer is usually made of a red organic luminescent material, the green light-emitting sub-layer is usually made of a green organic luminescent material, and the blue light-emitting sub-layer is usually made of a blue organic luminescent material. Of course, the first light-emitting sub-layer may also be a green light-emitting sub-layer or a blue light-emitting sub-layer, the second light-emitting sub-layer may also be a red light-emitting sub-layer or a blue light-emitting sub-layer, and the third light-emitting sub-layer may also be a red light-emitting sub-layer or a green light-emitting sub-layer, which is also applicable to the embodiments of the present disclosure.

In some examples, with continued reference to FIG. 5, a light-emitting area of the blue light-emitting sub-layer may be greater than a light-emitting area of the red light-emitting sub-layer or a light-emitting area of the green light-emitting sub-layer. For example, an area of an orthographic projection of the third light-emitting sub-layer 223 on the substrate 10 is greater than an area of an orthographic projection of the first light-emitting sub-layer 221 on the substrate 10, and the area of the orthographic projection of the third light-emitting sub-layer 223 on the substrate 10 is greater than an area of an orthographic projection of the second light-emitting sub-layer 222 on the substrate 10. The resistivity of the blue organic luminescent material is usually greater than the resistivity of the green organic luminescent material and the resistivity of the red organic luminescent material. The increase in the light-emitting area of the blue light-emitting sub-layer may enhance the luminance uniformity of the light-emitting devices L, thereby improving the uniformity of the display effect of the display panel 100.

In some examples, the light-emitting sub-layers may further include an auxiliary light-emitting layer that helps a light-emitting sub-layer emit light, and the auxiliary light-emitting layer includes, for example, one or more film layers of a hole injection layer (HIL), a hole transport layer (HTL), an electron blocking layer (EBL), a hole blocking layer (HBL), an electron transport layer (ETL) and an electron injection layer (EIL).

With continued reference to FIGS. 4 and 5, the anode layer 21 includes a plurality of anodes 211, and the anodes 211 are connected to the circuit layer 12. The anodes 211 are connected to the pixel circuits in the circuit layer 12. For example, an anode 211 is connected to a pixel circuit through a via hole. For example, the anode 211 is connected to a drain in the source-drain metal layer through a via hole extending through the planarization layer. The light-emitting sub-layers correspond one-to-one with the anodes 211. The material of the anode 211 is, for example, a metal oxide such as indium tin oxide (ITO) or indium zinc oxide (IZO), or a metal such as silver (Ag), aluminum (Al) and molybdenum (Mo) or an alloy thereof.

The cathode layer 23 includes a plurality of cathodes 231. The material of the cathode 231 may include a metal such as magnesium (Mg), calcium (Ca), lithium (Li) or aluminum (Al) or an alloy thereof, or a metal oxide such as IZO and zinc tin oxide (ZTO), or an organic material with conductive properties such as PEDOT/PSS (poly (3,4-ethylenedioxythiophene):poly (styrene sulfonate)).

FIG. 6 is a diagram showing a relationship between luminance and voltage of a sub-pixel.

The luminance of the sub-pixel is correlation with a voltage applied to the sub-pixel. Referring to FIG. 6, within a certain voltage range, the luminance of the sub-pixel SP is substantially positive correlation with the voltage applied thereto. For example, for the red sub-pixel R, within a certain voltage range, the greater the voltage applied to the red sub-pixel, the greater the luminance of the red sub-pixel R; for the green sub-pixel G, within a certain voltage range, the greater the voltage applied to the green sub-pixel, the greater the luminance of the green sub-pixel G; and for the blue sub-pixel B, within a certain voltage range, the greater the voltage applied to the blue sub-pixel, the greater the luminance of the blue sub-pixel B.

In some implementations, the plurality of cathodes are interconnected to achieve a coplanar cathode. Since all the cathodes are interconnected, a voltage signal on a cathode will be transmitted to all the cathodes through the interconnected cathodes, so that voltage signals on the cathodes of all the light-emitting devices L are the same, resulting in the same cathode voltage Vss of sub-pixels for emitting lights of different colors.

With continued reference to FIG. 6, the sub-pixels SP for emitting lights of different colors require different voltages to emit light. In a case where each sub-pixel emit light of the same luminance, a voltage required for the blue sub-pixel B to emit light is greater than a voltage required for the red sub-pixel R to emit light and a voltage required for the green sub-pixel G to emit light. Therefore, in a case where the cathodes in the cathode layer 23 are interconnected, in order to make the blue sub-pixel B emit light, the cathode layer 23 has a relatively large cathode voltage Vss. In this case, voltages actually required by the red sub-pixel R and the green sub-pixel G are smaller than the cathode voltage Vss, and thus a current Ivss of the red light-emitting sub-layer corresponding to the red sub-pixel R and a current Ivss of the green light-emitting sub-layer corresponding to the green sub-pixel G are larger than a current required for emitting light, resulting in an increase in power consumptions of the red sub-pixel R and the green sub-pixel G, thereby increasing the power consumption of the entire pixel P, and further increasing the power consumption of the display panel 100 and reducing the display performance of the display panel 100.

In order to solve the above problem, in some embodiments, a plurality of cathodes 231 are separate from one another, and each cathode 231 corresponds to at least one sub-pixel SP. The term “separate from one another” here means that the cathodes 231 are not connected.

Each cathode 231 corresponding to at least one sub-pixel SP means that each cathode serves as a cathode of light-emitting device(s) of the at least one sub-pixel. For example, one cathode 231 corresponds to one sub-pixel SP. That is, a plurality of sub-pixels SP do not share a cathode 231. For example, the first sub-pixel, the second sub-pixel and the third sub-pixel each correspond to a cathode 231, a cathode of a light-emitting device of the first sub-pixel, a cathode of a light-emitting device of a second sub-pixel and a cathode of a light-emitting device of a third sub-pixel are cathodes that are separate from one another, and the three cathodes 231 are separate from one another and not connected to each other. As another example, one cathode 231 corresponds to multiple sub-pixels SP for emitting light of the same color. That is, two or more sub-pixels SP for emitting light of the same color share a cathode 231. For example, the plurality of sub-pixels SP further include a fourth sub-pixel, the fourth sub-pixel emits light of the same color as the first sub-pixel, and the first sub-pixel and the fourth sub-pixel correspond to the same cathode 231. As another example, the display panel 100 includes a plurality of columns of sub-pixels, a column of sub-pixels includes multiple sub-pixels for emitting light of the same color, and the column of sub-pixels correspond to the same cathode 231.

In order to be connected to the circuit layer 12, the display panel 100 further includes a plurality of connection portions 30, and a cathode 231 is connected to the circuit layer 12 by at least one connection portion 30. In order to prevent short circuit, the connection portions 30 and the anodes 211 are not in contact with each other.

The connection portions 30 are disposed on a side of the substrate 10. In a direction parallel to a plane where the substrate 10 is located (e.g., the first direction X), the connection portion(s) 30 are located on at least one side (e.g., one side or multiple sides) of the cathode 231. For example, with continued reference to FIG. 4, a connection portion 30 is provided on a side of a cathode 231, and each part of the connection portion 30 is located on the same side of the cathode 231. As another example, multiple connection portions 30 are provided on a side of a cathode 231, and each part of each connection portion 30 in the multiple connection portions 30 is located on the same side of the cathode 231. As another example, all parts of a connection portion 30 are located on both sides of a cathode 231. As another example, multiple connection portions 30 are provided on both sides of a cathode, the cathode 231 is connected to the connection portions 30 on both sides, and the connection portions 30 on both sides are connected to the circuit layer 12. As another example, connection portions 30 are provided around a cathode 231, the cathode 231 is connected to the surrounding connection portions 30, and the surrounding connection portions 30 are connected to the circuit layer 12.

In the embodiments of the present disclosure, the plurality of cathodes 231 are separate from one another, each cathode 231 corresponds to at least one sub-pixel SP, and the connection portion 30 is provided to realize the connection between the cathode 231 and the circuit layer 12. Therefore, each cathode is provided, by the circuit layer 12, with a separate voltage signal. In this way, each cathode 231 may correspond to a separate cathode voltage Vss, and cathode voltages Vss of sub-pixels for emitting lights of different colors may be adjusted separately depending on actual needs, so as to achieve a differentiation of cathode voltages Vss of sub-pixels corresponding to different cathodes. The voltage of the sub-pixel SP may be substantially equal to the actually required voltage, and the luminance of the sub-pixel is adapted to the cathode voltage. For example, an actual voltage of the blue sub-pixel B may be greater than an actual voltage of the red sub-pixel R and an actual voltage of the green sub-pixel G, so that currents Ivss in the blue light-emitting sub-layer corresponding to the blue sub-pixel B, the red light-emitting sub-layer corresponding to the red sub-pixel R and the green light-emitting sub-layer corresponding to the green sub-pixel G are all adapted to the required current, so as to reduce the power consumption of the sub-pixels SP, thereby reducing the power consumption of the pixel P, and further reducing the power consumption of the display panel 100 and improving the display performance of the display panel 100.

In some embodiments, with continued reference to FIG. 5, the circuit layer 12 further includes a plurality of signal lines. The plurality of signal lines include a first signal line 121, a second signal line 122 and a third signal line 123. The first signal line 121, the second signal line 122 and the third signal line 123 are all configured to transmit cathode voltage signals, and the transmitted cathode voltage signals have different voltages. The cathode 231 is connected to a connection portion 30, the connection portion 30 is connected to a signal line, the signal line is connected to the cathode voltage signal bus, and the cathode voltage signal bus is configured to transmit a cathode voltage signal. The material of the signal line may be a conductive material such as titanium (Ti), aluminum (Al), copper (Cu) or molybdenum (Mo). The circuit layer 12 may include a metal layer, and the metal layer is located on a side of the base substrate 11 proximate to the light-emitting device layer 20. For example, the first signal line 121, the second signal line 122 and the third signal line 123 are located in the same metal layer of the circuit layer 12, that is, a plurality of signal lines may all be formed in the same metal layer, so that the number of metal layers may be reduced, thereby simplifying process steps and improving an production efficiency of products. Moreover, the plurality of signal lines are located in the same metal layer, and there is no need to provide an insulating layer between adjacent metal layers, thereby reducing the number of film layers in the display panel 100, and further reducing a dimension of the display panel 100 in the third direction Z. Alternatively, the circuit layer 12 may include a plurality of metal layers, and the plurality of signal lines are located in the plurality of metal layers. For example, any two signal lines in the first signal line 121, the second signal line 122 and the third signal line 123 are located in the same metal layer, and the first signal line 121, the second signal line 122 and the third signal line 123 are each connected to the cathode voltage signal bus. As another example, the plurality of metal layers include a first metal layer, a second metal layer and a third metal layer, the first signal line 121 is located in the first metal layer, the second signal line 122 is located in the second metal layer, the third signal line 123 is located in the third metal layer, and the plurality of signal lines are located in different metal layers. In some implementations, in a case where the circuit layer 12 includes a plurality of metal layers, the plurality of signal lines may also be located in the same metal layer.

In the same pixel P, sub-pixels for emitting lights of different colors are connected to different signal lines. For example, in a pixel P, a cathode 231 of the first sub-pixel is connected to the first signal line 121, a cathode 231 of the second sub-pixel is connected to the second signal line 122, and a cathode 231 of the third sub-pixel is connected to the third signal line 123. As another example, the pixel P further includes a fourth sub-pixel. If the fourth sub-pixel and the first sub-pixel both emit red light, a cathode of the fourth sub-pixel is connected to the first signal line 121, the cathode voltage signal bus transmits a voltage signal to the first signal line 121, the first signal line 121 transmits a signal to the cathodes of the first sub-pixel and the fourth sub-pixel, and the first sub-pixel and the fourth sub-pixel have the same cathode voltage Vss. If the fourth sub-pixel and the second sub-pixel both emit green light, a cathode of the fourth sub-pixel is connected to the second signal line 122, the cathode voltage signal bus transmits a voltage signal to the second signal line 122, the second signal line 122 transmits a signal to the cathodes of the second sub-pixel and the fourth sub-pixel, and the second sub-pixel and the fourth sub-pixel have the same cathode voltage Vss. If the fourth sub-pixel and the third sub-pixel both emit blue light, a cathode of the fourth sub-pixel is connected to the third signal line 123, the cathode voltage signal bus transmits a voltage signal to the third signal line 123, the third signal line 123 transmits a signal to the cathodes of the third sub-pixel and the fourth sub-pixel, and the third sub-pixel and the fourth sub-pixel have the same cathode voltage Vss.

In different pixels P, sub-pixels for emitting light of the same color may be connected to the same signal line. For example, the plurality of pixels P include a first pixel P1 and a second pixel P2, a red sub-pixel R in the first pixel P1 and a red sub-pixel R in the second pixel P2 are both connected to the first signal line 121, a green sub-pixel G in the first pixel P1 and a green sub-pixel G in the second pixel P2 are both connected to the second signal line 122, and a blue sub-pixel B in the first pixel P1 and a blue sub-pixel B in the second pixel P2 are both connected to the third signal line 123.

The cathodes 231 corresponding to the sub-pixels for emitting light of the same color are connected to the same signal line. The same signal line controls voltages of the sub-pixels for emitting light of the same color, and thus signal transmission efficiency may be improved.

In some embodiments, with continued reference to FIG. 5, the pixel circuit is not in contact with any signal line in the plurality of signal lines. For example, the pixel circuit is not in contact with the first signal line 121, the second signal line 122 and the third signal line 123. Since the pixel circuit and the signal line are not in contact with each other, the anode 211 is connected to the pixel circuit, and the cathode 231 is connected to the signal line. Therefore, the anode 211 cannot be connected to the cathode 231 by the pixel circuit, and the cathode 231 cannot be connected to the anode 211 by the signal line. This may reduce a problem of signal disorder caused by interconnection of cathodes and anodes between all the sub-pixels.

For example, with continued reference to FIG. 5, the display panel 100 includes a base substrate 11, and a gate layer 124, a first source-drain metal layer 125 and a second source-drain metal layer 126 that are disposed on a side of the base substrate 11. The gate layer 124 is, for example, the first metal layer mentioned above, the first source-drain metal layer 125 is, for example, the second metal layer mentioned above, and the second source-drain metal layer 126 is, for example, the third metal layer mentioned above. In some examples, the third signal line 123 is located in the same layer as the gate of the thin film transistor, that is, both are located in the gate layer 124; the second signal line is located in the first source-drain metal layer; and the first signal line 121 is located in the same layer as the source and the drain of the thin film transistor, that is, both are located in the second source-drain metal layer.

FIG. 7 is a structural diagram of another display panel in accordance with some embodiments of the present disclosure.

In some embodiments, at least one (e.g., one or more) connection portion in the plurality of connection portions is a first connection portion 31, and the cathode 231 is connected to the circuit layer 12 by the first connection portion 31. In the plurality of sub-pixels SP of the display panel 100, a cathode 231 of at least one (e.g., one or more) sub-pixels SP is connected to the circuit layer 12 by the first connection portion 31.

For example, the display panel 100 includes a plurality of pixels P, each pixel P includes multiple sub-pixels SP, and a cathode 231 of at least one (e.g., one or more) sub-pixel SP of part of the plurality of pixels P is connected to the circuit layer 12 by a first connection portion 31, and sub-pixels SP of another part of the plurality of pixels P are not connected to the circuit layer 12 by a first connection portion 31, for example, are connected to the circuit layer 12 by a second connection portion 32 (described in detail below). As another example, the display panel 100 includes a plurality of pixels P, each pixel P includes multiple sub-pixels SP, and a cathode 231 of at least one (e.g., one or more) sub-pixel SP of each pixel P is connected to the circuit layer 12 by a first connection portion 31. For example, referring to FIGS. 4 and 7, the first pixel P1 (not shown in FIG. 7) includes a first sub-pixel, a second sub-pixel and a third sub-pixel. A cathode 231 of the first sub-pixel is connected to a first connection portion 31, the first connection portion 31 is connected to a signal line through a via hole in the circuit layer 12, and cathodes of the second sub-pixel and/or the third sub-pixel may each be connected to another first connection portion 31. Moreover, a cathode 231 of at least one (e.g., one or more) sub-pixels SP in the second pixel P2 (not shown in FIG. 7) is also connected to the circuit layer 12 by a first connection portion 31.

The first connection portion 31 includes a first connection column 311. The first connection column 311 is disposed on a side of the substrate 10, the cathode 231 is connected to the first connection column 311, and the first connection column 311 is connected to the circuit layer 12. For example, referring to FIG. 7, the first connection column 311 is connected to a cathode 231a, and the first connection column 311 is connected to a signal line in the metal layer through a via hole in the circuit layer 12. The material of the first connection column 311 may be a conductive material such as titanium (Ti), aluminum (Al), copper (Cu) or molybdenum (Mo) that can realize signal transmission.

During formation of the first connection portion 31, the via hole may be formed in the circuit layer 12 to expose the signal line to be connected, and the conductive material is deposited using a thin film deposition process such as chemical vapor deposition (CVD), physical vapor deposition (PVD) or atomic layer deposition (ALD) to form a connection layer laid on the circuit layer 12, and then a pattern processing is performed by etching to form the first connection column 311. Since the first connection portion 31 has a simple structure, a process of forming the first connection portion 31 is simple and the first connection portion 31 is easy to form.

In some embodiments, with continued reference to FIG. 7, the first connection column 311 has an overall structure of being narrow at the top and wide at the bottom. The first connection column 311 includes a first end 3111 away from the substrate 10 and a second end 3112 proximate to the substrate 10, and an orthographic projection of the first end 3111 on the substrate 10 is located within an orthographic projection of the second end 3112 on the substrate 10. That is, in a direction (e.g., the first direction X) parallel to an XY plane (e.g., a plane defined by the first direction X and the second direction Y), a dimension of the first end 3111 is smaller than a dimension of the second end 3112. For example, a cross section of the first connection column 311 in an XZ plane (e.g., a plane defined by the first direction X and the third direction Z) may be of a trapezoidal structure, and the dimension of the first connection column 311 gradually increases from the first end 3111 to the second end 3112 in a direction approaching the substrate 10. A boundary of an orthographic projection of a side of the first connection column 311 away from the first end 3111 on the substrate 10 exceeds a boundary of an orthographic projection of the first end 3111 on the substrate 10. When the cathode 231 is formed by deposition or evaporation, the conductive material is deposited from a side of the connection portion 30 away from the substrate 10 to a position of an adjacent cathode 231, and the conductive material is first in contact with the side of the first connection column 311 away from the first end 3111 to ensure connection between the connection portion 30 and the cathode 231. In some embodiments, with continued reference to FIG. 7, at least one (e.g., one or more) connection portion 30 in the plurality of connection portions is a second connection portion 32, and the cathode 231 is connected to the circuit layer 12 by the second connection portion 32. In the plurality of sub-pixels SP of the display panel 100, a cathode 231 of at least one (e.g., one or more) sub-pixels SP is connected to the circuit layer 12 by the second connection portion 32.

For example, the display panel 100 includes a plurality of pixels P, each pixel P includes multiple sub-pixels SP, and a cathode 231 of at least one (e.g., one or more) sub-pixel SP of part of the plurality of pixels P is connected to the circuit layer 12 by a second connection portion 32, and sub-pixels SP of another part of the plurality of pixels P are not connected to the circuit layer 12 by a second connection portion 32, for example, are connected to the circuit layer 12 by a first connection portion 31. As another example, the display panel 100 includes a plurality of pixels P, each pixel P includes multiple sub-pixels SP, and a cathode 231 of at least one (e.g., one or more) sub-pixel SP of each pixel P is connected to the circuit layer 12 by a second connection portion 32. As another example, the display panel 100 includes a plurality of pixels P, the pixel P includes a plurality of sub-pixels SP, the cathode 231 of at least one (e.g., one, or multiple) sub-pixel SP of each pixel P is connected to the circuit layer 12 via the second connection portion 32. For example, referring to FIGS. 4 and 7, the first pixel P1 (not shown in FIG. 7) includes a first sub-pixel, a second sub-pixel and a third sub-pixel. A cathode 231 of the second sub-pixel is connected to a second connection portion 32, the second connection portion 32 is connected to a signal line through a via hole in the circuit layer 12. Cathodes of the first sub-pixel and/or the third sub-pixel may each be connected to another second connection portion 32; alternatively, cathodes of the first sub-pixel and/or the third sub-pixel may also each be connected to a first connection portion 31. Moreover, a cathode 231 of at least one (e.g., one or more) sub-pixels SP in the second pixel P2 (not shown in FIG. 7) is also connected to the circuit layer 12 by a second connection portion 32.

The second connection portion 32 includes a second connection column group 321 and a first connection sub-portion 322. The first connection sub-portion 322 is disposed on a side of the second connection column group 321 proximate to the substrate 10.

The second connection column group 321 includes at least one (e.g., one or more) second connection column 3211. The second connection column 3211 is disposed on a side of the first connection sub-portion 322 away from the substrate 10. The second connection column 3211 includes a third end 81 away from the substrate 10 and a fourth end 82 proximate to the substrate. A plurality of second connection columns 3211 are not in contact one another. For example, orthographic projections of the plurality of second connection columns 3211 on the substrate 10 do not overlap.

The cathode 231 is connected to at least one of the second connection column group 321 and the first connection sub-portion 322, and the second connection portion 32 is connected to the circuit layer 12. The materials of the second connection column group 321 and the first connection sub-portion 322 are both conductive materials. As for the conductive material, reference may be made to the above description, and details are not repeated here. The cathode voltage signal bus transmits a cathode voltage signal of each cathode to the signal line, and the cathode voltage signal is transmitted to the second connection column group 3211 through the first connection sub-portion 322.

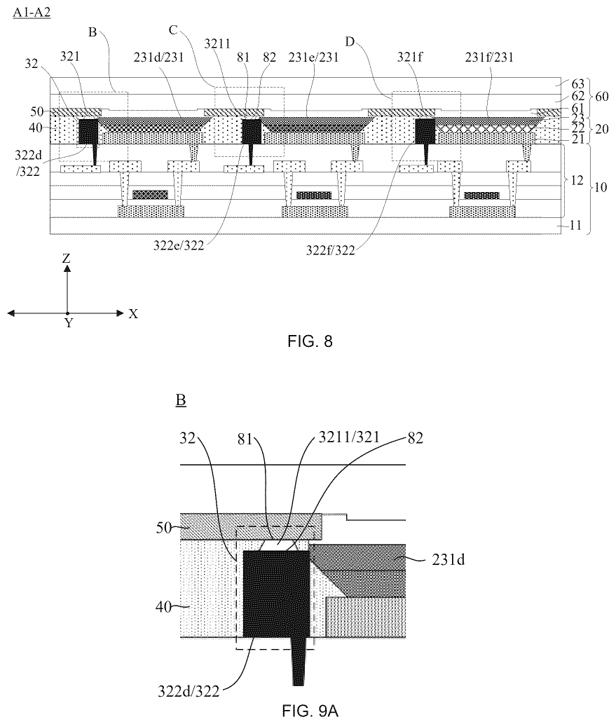

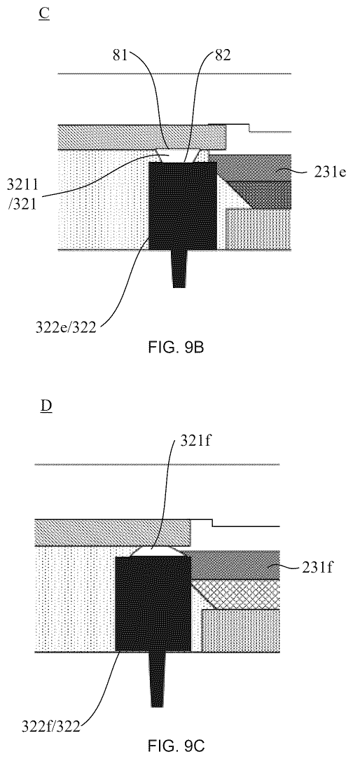

For example, with continued reference to FIG. 7, the cathode 231 is connected to the second connection column group 321, and the cathode 231 is not connected to the first connection sub-portion 322. In this case, the second connection column group 321 is connected to the first connection sub-portion 322, the first connection sub-portion 322 is connected to the signal line through a via hole in the circuit layer 12, and the cathode voltage signal is transmitted to the cathode 231 through the first connection sub-portion 322 and the second connection column group 321. For example, the second connection column group 321 includes one second connection column 3211, a cathode 231b is connected to the second connection column 3211, the second connection column 3211 is connected to a first connection sub-portion 322b, the first connection sub-portion 322b is connected to the circuit layer 12, and the cathode voltage signal is transmitted to the cathode 231 through the circuit layer 12, the first connection sub-portion 322b and the second connection column 3211. As another example, the second connection column group 321 includes multiple second connection columns 3211, a cathode 231c is connected to at least one (e.g., one or more) second connection columns 3211, and the multiple second connection columns 3211 are all connected to a first connection sub-portion 322c, and the cathode voltage signal is transmitted to the cathode 231 through the circuit layer 12, the first connection sub-portion 322c and the multiple second connection columns 3211. FIG. 8 is a structural diagram of another display panel in accordance with some embodiments of the present disclosure. FIG. 9A is an enlarged view of an area B in FIG. 8. FIG. 9B is an enlarged view of an area C in FIG. 8.

As another example, referring to FIGS. 8, 9A and 9B, the cathode 231 is connected to the first connection sub-portion 322, and the cathode 231 is not connected to the second connection column group 321. In this case, the first connection sub-portion 322 is connected to the signal line through the via hole in the circuit layer 12, and the cathode voltage signal is transmitted to the cathode 231 through the first connection sub-portion 322.

For example, with continued reference to FIG. 9A, a cathode 231d is connected to a first connection sub-portion 322d, and the cathode 231d is not connected to the second connection column group 321. That is, the cathode 231d is not connected to any second connection column 3211. The first connection sub-portion 322d is connected to the signal line through the via hole in the circuit layer 12, and the cathode voltage signal is transmitted to the cathode 231d through the circuit layer and the first connection sub-portion 322d.

As another example, with continued reference to FIG. 9B, a cathode 231e is connected to a first connection sub-portion 322e, and the cathode 231e is not connected to any second connection column 3211 in the second connection column group 321. The first connection sub-portion 322e is connected to the signal line through the via hole in the circuit layer, and the cathode voltage signal is transmitted to the cathode 231e through the circuit layer and the first connection sub-portion 322e.

FIG. 9C is an enlarged view of an area D in FIG. 8.

As another example, referring to FIGS. 8 and 9C, the cathode 231 is connected to both the second connection column group 321 and the first connection sub-portion 322. In this case, the first connection sub-portion 322 is connected to the signal line through the via hole in the circuit layer 12, and the cathode voltage signal may be directly transmitted to the cathode 231 through the first connection sub-portion 322, or the cathode voltage signal may be transmitted to the cathode 231 through the first connection sub-portion 322 and the second connection column group 321. For example, referring to FIG. 9C, a second connection column group 321f and a first connection sub-portion 322f are both connected to a cathode 231f, and thus the connection strength between the cathode 231f and the second connection portion 32 may be enhanced, which is beneficial to signal transmission.

In some embodiments, with continued reference to FIG. 7, in a case where the cathode 231 is only connected to the second connection column group 321, the second connection column group 321 is connected to the first connection sub-portion 322, and a second connection column 3211 in the second connection column group 321 connected to the cathode 231 has an overall structure of being narrow at the top and wide at the bottom. An orthographic projection of a third end 81 of a second connection column 3211 in the second connection column group 321 connected to the cathode 231 on the substrate 10 is located within an orthographic projection of a fourth end 82 thereof on the substrate 10. That is, in a direction parallel to the XY plane, a dimension of the third end 81 is smaller than a dimension of the fourth end 82. For example, a cross section of the second connection column 3211 in the XZ plane may be of a trapezoidal structure, and the dimension of the second connection column 3211 gradually increases from the third end 81 to the fourth end 82 in the direction approaching the substrate 10. A boundary of an orthographic projection of a side of the second connection column 3211 away from the third end 81 on the substrate 10 exceeds a boundary of an orthographic projection of the third end 81 on the substrate 10. When the cathode 231 is formed by deposition or evaporation, the conductive material is deposited from a side of the connection portion 30 away from the substrate 10 to a position of an adjacent cathode 231, and the conductive material is first in contact with the side of the second connection column 3211 away from the third end 81, which is conducive to the connection between the second connection portion 32 and the cathode 231.

In some embodiments, with continued reference to FIGS. 8 and 9B, in a case where the cathode 231 is only connected to the first connection sub-portion 322, a second connection column 3211 has an overall structure of being wide at the top and narrow at the bottom. An orthographic projection of a fourth end 82 of a second connection column 3211 on the substrate 10 is located within an orthographic projection of a third end 81 thereof on the substrate 10. That is, in a direction parallel to the XY plane, a dimension of the third end 81 is larger than a dimension of the fourth end 82. For example, a cross section of the second connection column 3211 in the XZ plane may be of an inverted trapezoidal structure, and the dimension of the second connection column 3211 gradually decreases from the third end 81 to the fourth end 82 in the direction approaching the substrate 10. The third end 81 has the largest dimension. During formation of the light-emitting sub-layer and the cathode by evaporation, the light-emitting sub-layer and the cathode may be disconnected at an edge of the second connection column 3211, so as to prevent interconnection between light-emitting sub-layers of sub-pixels for emitting lights of different colors and interconnection between cathode 231 of sub-pixels for emitting lights of different colors, thereby reducing signal disorder. In some implementations, in a case where the cathode 231 is only connected to the first connection sub-portion 322, the second connection column 3211 may alternatively has an overall structure of being narrow at the top and wide at the bottom.

In some embodiments, the cathode 231 is connected to the second connection portion 32, and the second connection column group 321 in the second connection portion 32 includes multiple second connection columns 3211. A second connection column 3211 closest to the cathode 231 (the cathode connected to the second connection portion 32) in the multiple second connection columns 3211 is a selected second connection column, and an orthographic projection of the selected second connection column on the substrate 10 is located within an orthographic projection of the first connection sub-portion 322 on the substrate 10. Here, the term “closest” may mean that in the first direction X, a distance between the selected second connection column and the cathode 231 is the smallest compared to distances between other second connection column 3211 in the second connection column group 321 and the cathode 231. In the direction parallel to the XY plane, a dimension of the selected second connection column is smaller than a dimension of the first connection sub-portion 322, and a boundary of the orthographic projection of the first connection sub-portion 322 on the substrate 10 exceeds a boundary of the orthographic projection of the selected second connection column on the substrate 10. When the cathode 231 is formed by deposition or evaporation, the conductive material is deposited from a side of the connection portion 30 away from the substrate 10 to a position of an adjacent cathode 231, and the conductive material is first in contact with first connection sub-portion 322, and the cathode 231 is easy to be connected to the first connection sub-portion 322, which is conducive to the connection between the second connection portion 32 and the cathode 231.

In some embodiments, the plurality of connection portions include a first connection portion 31 and/or a second connection portion 32. For example, the plurality of connection portions include first connection portions 31. Each cathode is connected to the circuit layer 12 by a first connection portion 31, that is, a cathode of each sub-pixel is connected to the first connection portion 31. As another example, the plurality of connection portions include second connection portions 32. Each cathode is connected to the circuit layer 12 by a second connection portion 32, that is, a cathode of each sub-pixel is connected to the second connection portion 32. As another example, the plurality of connection portions include first connection portions 31 and second connection portions 32. In the plurality of cathodes, some cathodes are connected to the circuit layer 12 by first connection portion 31, some other cathodes are connected to the circuit layer 12 by second connection portion 32, and there may be some cathodes that are connected to both first connection portion 31 and second connection portion 32. The cathodes may be connected to the circuit layer 12 by different connection portions 30.

A connection portion connected to a cathode of at least one sub-pixel is the first connection portion 31, and/or a connection portion connected to a cathode of at least one sub-pixel is the second connection portion 32.

For example, the connection portion connected to the cathode of the at least one (e.g., one or more) sub-pixel is the first connection portion 31. The cathode connected to the first connection portion 31 may be cathodes of different sub-pixels SP in the same pixel P, or may be cathodes of different sub-pixels SP in different pixels P. As another example, the connection portion connected to the cathode of the at least one (e.g., one or more) sub-pixel is the second connection portion 32. The cathode connected to the second connection portion 32 may be cathodes of different sub-pixels SP in the same pixel P, or may be cathodes of different sub-pixels SP in different pixels P. As another example, the connection portion connected to the cathode of the at least one (e.g., one or more) sub-pixel is the first connection portion 31, and the connection portion connected to the cathode of the at least one (e.g., one or more) sub-pixel is the second connection portion 32. In multiple cathodes of different sub-pixels SP in the same pixel P, some cathodes are connected to first connection portions 31, and some other cathodes are connected to second connection portions 32. In different pixels P, multiple cathodes of different sub-pixels SP in a pixel P are all connected to first connection portions 31, and multiple cathodes of different sub-pixels SP in another pixel P are all connected to second connection portions 32. A cathode of a sub-pixel in the same pixel P is connected to both the first connection portion 31 and the second connection portion 32.

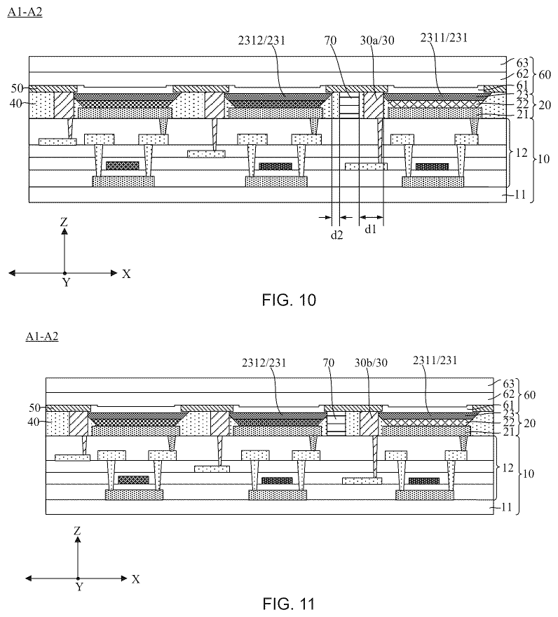

FIG. 10 is a structural diagram of another display panel in accordance with some embodiments of the present disclosure.

In some embodiments, referring to FIG. 10, the display panel 100 further includes a partition portion 70. In a direction parallel to the plane where the substrate 10 is located, the partition portion 70 and the connection portion 30 are located on the same side of the cathode 231 connected to the connection portion 30. For example, in adjacent cathodes, a cathode connected to a connection portion 30a is a first cathode 2311, and the other cathode is a second cathode 2312. The first cathode 2311 is located on a side of the second cathode 2312, and the partition portion 70 and the connection portion 30a are both located on a side of the first cathode 2311 proximate to the second cathode 2312. For example, in the first direction X, the second cathode 2312, the partition portion 70, the connection portion 30 and the first cathode 2311 are arranged in sequence. In this way, the partition portion 70 may further prevent adjacent cathodes 231 from being connected to each other. An orthographic projection of the partition portion 70 on the substrate 10 does not overlap with the orthographic projection of the connection portion 30 on the substrate 10, so as to prevent disorder of signal transmission caused by connection between the partition portion 70 and the connection portion 30. The partition portion 70 is not connected to the signal line. During formation of the partition portion 70, there is no need to provide a via hole, connected to the partition portion 70, in the circuit layer 12, and the partition portion 70 may be directly formed on a side of the circuit layer 12 away from the base substrate 11. A material of the partition portion 70 may be a conductive material or an insulating material.

In some embodiments, with continued reference to FIG. 10, a distance between the partition portion 70 and the cathode 231 is greater than or equal to 2 μm. A distance between a boundary of an orthographic projection of the partition portion 70 on the substrate 10 and a boundary of an orthographic projection of the cathode 231 on the substrate 10 is greater than or equal to 2 μm, for example, equal to 2 μm, 2.5 μm or 3 μm. For example, a distance between the boundary of the orthographic projection of the partition portion 70 on the substrate 10 and a boundary of an orthographic projection of the first cathode 2311 on the substrate 10 is a first distance d1, and the first distance d1 is greater than or equal to 2 μm, for example, equal to 2 μm, 2.5 μm or 3 μm. In addition, a distance between the boundary of the orthographic projection of the partition portion 70 on the substrate 10 and a boundary of an orthographic projection of the second cathode 2312 on the substrate 10 is a second distance d2, and the second distance d2 is greater than or equal to 2 μm, for example, equal to 2 μm, 2.5 μm or 3 μm. The first distance d1 and the second distance d2 may be the same or different. A distance is maintained between the partition portion 70 and the cathode 231, so that the partition portion 70 and the cathode 231 are not in contact.

FIG. 11 is a structural diagram of another display panel in accordance with some embodiments of the present disclosure.

In some embodiments, referring to FIG. 11, the connection portion 30 is connected to the first cathode 2311, and the partition portion 70 is connected to the second cathode 2312. In a case where the material of the partition portion 70 is a conductive material, a signal on a signal line connected to the second cathode 2312 may be transmitted to the partition portion 70. Since there is no overlap between the partition portion 70 and a connection portion 30b, a cathode voltage signal of the second cathode 2312 will not be transmitted to the connection portion 30b connected to the first cathode 2311, so that voltage signals provided by the circuit layer 12 to the first cathode 2311 and the second cathode 2312 may also be independent of each other. The partition portion 70 and the anode are not in contact with each other, so as to prevent the light-emitting sub-layer from not emitting light due to the same voltages between the cathode and the anode that is caused by connection between the cathode and the anode of the light-emitting device by the partition portion 70. In a case where the material of the partition portion 70 is an insulating material, the partition portion 70 may be in contact with the anode, and the cathode voltage signal of the second cathode 2312 cannot be transmitted to the anode through the partition portion, so that a voltage difference is maintained between the anode and the cathode, and the light-emitting sub-layer may emit light normally.

In some embodiments, with continued reference to FIG. 5, the display panel 100 further includes a pixel defining layer 40. The pixel defining layer 40 is disposed on a side of the substrate 10.

The pixel defining layer 40 includes a plurality of pixel openings 41, and the light-emitting devices L of the sub-pixels are disposed corresponding to the pixel openings 41. Each pixel opening 41 exposes a portion of the anode 211. The light-emitting sub-layers are disposed in the pixel openings 41 in a one-to-one correspondence. The light-emitting sub-layers are formed on the anode 211 exposed by the pixel openings 41. The cathodes 231 may be located in the pixel openings 41.

The pixel defining layer 40 further includes a pixel defining main body 42. The pixel defining main body 42 is located between two adjacent cathodes 231. The material of the pixel defining main body 42 includes, for example, an organic insulating material such as negative photoresist, polyimide and epoxy resin, so as to prevent interconnection between the cathodes 231. The connection portion 30 penetrates the pixel defining main body 42 to be connected to the circuit layer 12. During formation of the pixel defining layer 40, the connection portion 30 may be formed on a side of the substrate 10, and then the pixel defining layer 40 may be formed through a patterning process, so that the connection portion 30 corresponds to the via hole in the circuit layer 12, thereby ensuring the connection between the connection portion 30 and the signal line in the circuit layer 12.

The pixel defining layer 40 is formed through a patterning process, which includes: in a case where a pixel defining film is made of an inorganic material, the pixel defining film with a certain thickness may be formed by deposition; in a case where a pixel defining film is made of an organic material, the pixel defining film with a certain thickness may be formed by coating. The pixel defining film may have the same height as the connection portion 30. The pixel defining film covers the anode layer. The pixel defining film is patterned by photolithography to form the plurality of pixel openings 41, so as to obtain the pixel defining layer 40.

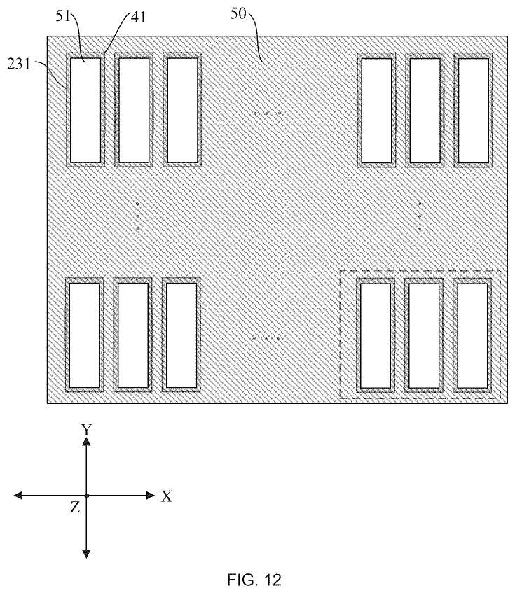

FIG. 12 is a top view of a structure of an isolation layer and a pixel defining layer in accordance with some embodiments of the present disclosure.

In some embodiments, with continued reference to FIG. 5, the display panel 100 further includes an isolation layer 50. The isolation layer 50 is disposed on a side of the pixel defining layer 40 away from the substrate 10. The material of the isolation layer 50 is an insulating material. For the insulating material, reference may be made to the above description, and details are not repeated here.

Referring to FIGS. 5 and 12, the isolation layer 50 includes a plurality of isolation openings 51, and the plurality of isolation openings 51 correspond to the plurality of pixel openings 41. A dimension d3 of an isolation opening 51 is smaller than a dimension d4 of the pixel opening 41 corresponding to the isolation opening 51. A boundary of the isolation layer 50 exceeds a boundary of the pixel defining main body directly opposite thereto, and the isolation layer 50 covers part of the pixel opening 41. During forming light-emitting sub-layers and cathodes in the pixel openings 41 by evaporation, the isolation layer 50 disconnects light-emitting sub-layers and cathodes in adjacent sub-pixels, so that the light-emitting sub-layers and the cathodes may be formed separately in the pixel openings 41, thereby preventing the cathodes 231 from being connected from one another. In some embodiments, with continued reference to FIG. 5, the via hole in the circuit layer 12 connected to the anode 211 is a first via hole 91. In a direction parallel to the plane where the substrate 10 is located, a distance between the first via hole 91 and a boundary of the anode 211 is a third distance d5. That is, a distance between a boundary of an orthogonal projection of the first via hole 91 on the substrate 10 and a boundary of an orthographic projection of the anode 211 connected to the first via hole 91 on the substrate 10 is the third distance d5. The third distance d5 is greater than or equal to 5 μm, for example, equal to 5 μm, 6 μm or 7 μm. In this way, it may avoid affecting the flatness of the anode 211 caused by depression of a portion of the anode 211 at an edge thereof due to an excessively small distance between the boundary of the anode 211 and the first via hole 91.

In some embodiments, with continued reference to FIG. 5, the connection portion 30 is connected to the circuit layer 12 through a second via hole 92. In a direction parallel to the plane where the substrate 10 is located, a distance between the second via hole 92 and the light-emitting sub-layer is a fourth distance d6. That is, a distance between a boundary of an orthogonal projection of the second via hole 92 on the substrate 10 and a boundary of an orthographic projection of the light-emitting sub-layer 220 corresponding to the connection portion 30 connected to the second via hole 92 on the substrate 10 is the fourth distance d6.

The pixel P includes a red light-emitting sub-layer, a green light-emitting sub-layer and a blue light-emitting sub-layer. A fourth distance d6 corresponding to the green light-emitting sub-layer is less than or equal to 2.8 μm, for example, equal to 2.8 μm, 2.5 μm, 2 μm or 1.5 μm. A fourth distance d6 corresponding to the red light-emitting sub-layer or the blue light-emitting sub-layer is less than or equal to 1.2 μm, for example, equal to 1.2 μm, 1 μm or 0.5 μm. Limiting the distance between the via hole and the light-emitting sub-layer may ensure flat surfaces of the connection portion 30 and the pixel defining layer 40 away from the isolation layer 50, which is beneficial to overlap between the connection portion 30 with the second via hole 92.

In some embodiments, with reference to FIG. 5, the display panel 100 further includes an encapsulation layer 60. The encapsulation layer 60 is located on a side of the light-emitting device layer 20 away from the substrate 10.

For example, the encapsulation layer 60 includes a first inorganic encapsulation layer 61, an organic encapsulation layer 62 and a second inorganic encapsulation layer 63. For example, the first inorganic encapsulation layer 61 and the second inorganic encapsulation layer 63 are formed by depositing, and the organic encapsulation layer 62 is formed by inkjet printing. For example, the first inorganic encapsulation layer 61, the organic encapsulation layer 62 and the second inorganic encapsulation layer 63 form a composite encapsulation layer. The materials of the first inorganic encapsulation layer 61 and the second inorganic encapsulation layer 63 may be inorganic materials such as silicon nitride, silicon oxide or silicon oxynitride, and the material of the organic encapsulation layer 62 may be an organic material such as polyimide (PI) or epoxy resin. Therefore, the encapsulation layer 60 may provide multiple protections for the functions and the structure of the display panel 100, thereby achieving a good encapsulation effect.

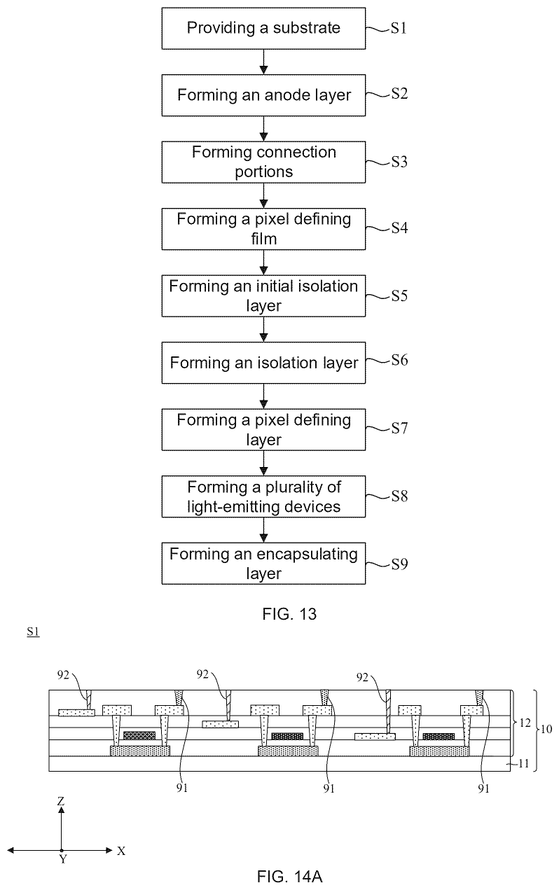

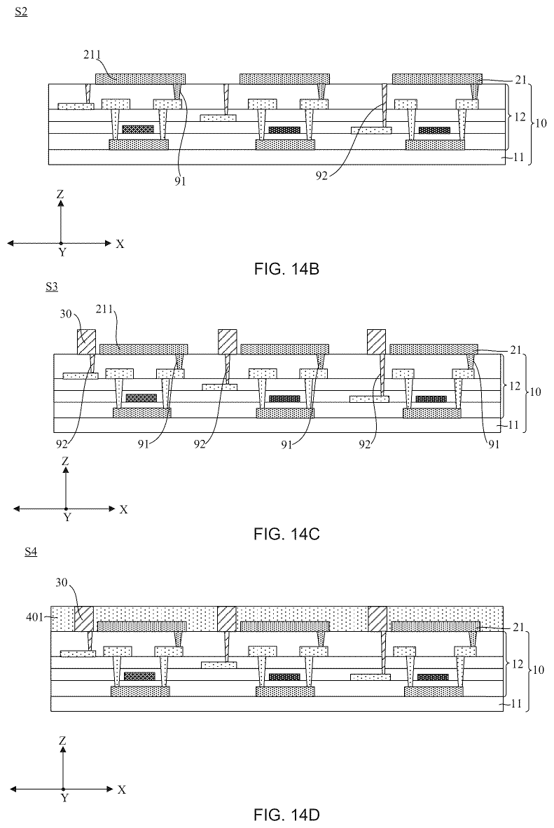

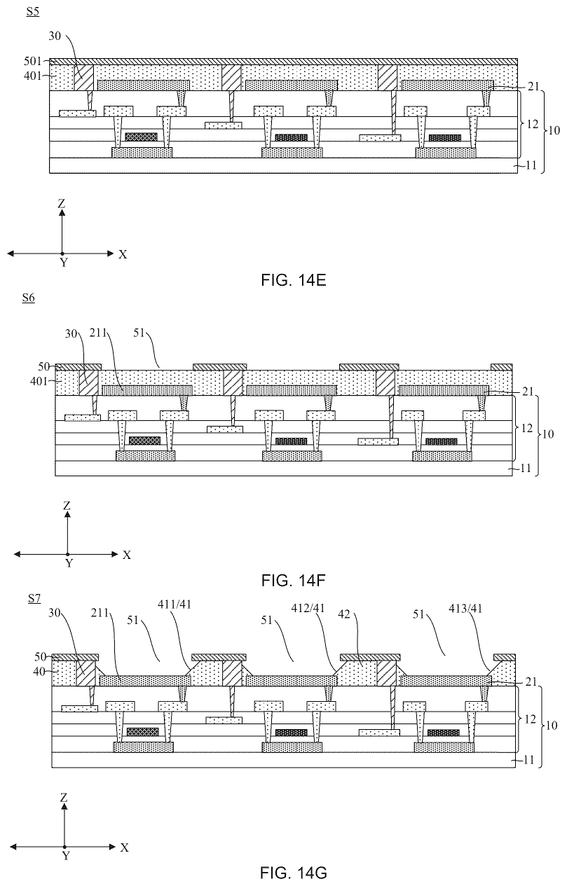

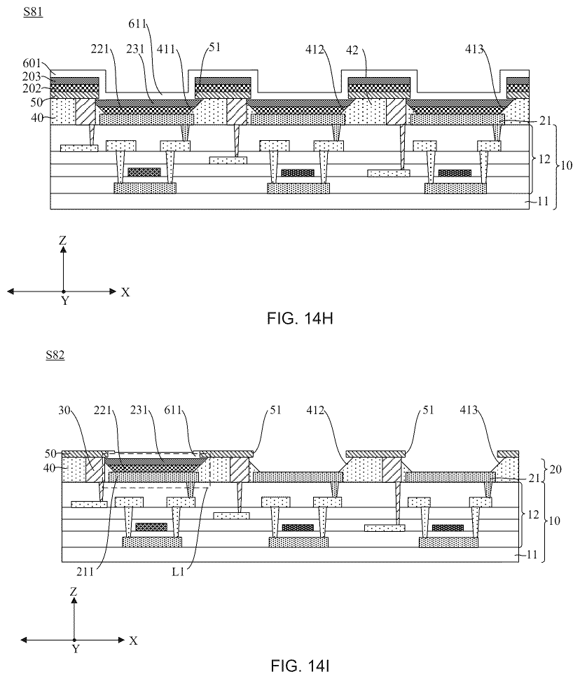

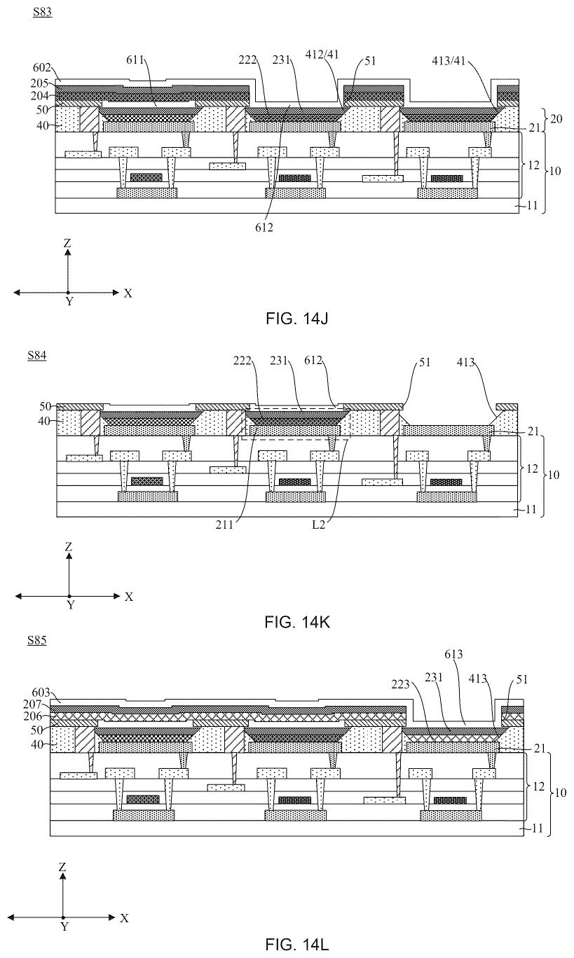

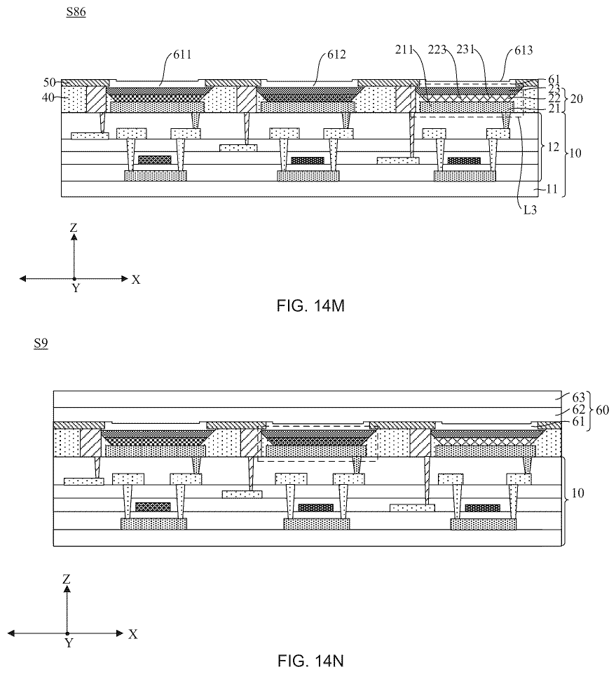

Embodiments of the present disclosure further provide a method for manufacturing a display panel. FIG. 13 is a flow diagram of a method for manufacturing a display panel in accordance with some embodiments of the present disclosure. FIGS. 14A to 14N are structural diagrams in steps of a method for manufacturing a display panel in accordance with some embodiments of the present disclosure.

The method for manufacturing the display panel provided in some embodiments of the present disclosure will be exemplarily described below with reference to the accompanying drawings. As shown in FIG. 13, the method for manufacturing the display panel includes steps S10 to S9.

In S1, a substrate 10 is provided.

FIG. 14A is a structural diagram of a substrate provided in some embodiments of the present disclosure.

Referring to FIG. 14A, the substrate 10 includes a base substrate 11 and a circuit layer 12. For the structure of the substrate 10, reference may be made to the above description, and details are not repeated here. The circuit layer 12 includes first via holes 91 and second via holes 92. The first via hole 91 exposes part of the pixel circuit, which is used to connect the pixel circuit in the circuit layer 12 with the anode formed subsequently; and the second via hole 92 exposes the signal line to be connected, and the second via hole 92 is used to connect the signal line in the circuit layer 12 with the connection portion 30 formed subsequently.

In S2, an anode layer 21 is formed.

FIG. 14B is a structural diagram of an anode layer provided in some embodiments of the present disclosure.

An initial anode layer is formed on a side of the circuit layer 12 away from the base substrate 11 and laid on the circuit layer 12, and then patterned by etching to form a plurality of anodes 211. Referring to FIG. 14B, the anode 211 is connected to the first via hole 91, and the anode 211 is connected to the pixel circuit through the first via hole 91.

In S3, connection portions 30 are formed.

FIG. 14C is a structural diagram of connection portions provided in some embodiments of the present disclosure.

A connection layer laid on the circuit layer 12 is formed by deposition, and then patterned by etching to form the connection portions 30. Referring to FIG. 14C, the connection portion 30 is connected to the second via hole 92 in the circuit layer 12, and the connection portion 30 is connected to a signal line in the circuit layer 12 through the second via hole 92. A height of the connection portion 30 is greater than a height of a cathode layer 23. In some examples, there is a gap between the connection portion 30 and the anode 211.

For the structure of the connection portion 30, reference may be made to the above description, and details are not repeated here.

In S4, a pixel defining film 401 is formed.

FIG. 14D is a structural diagram of a pixel defining film provided in some embodiments of the present disclosure.

Referring to FIG. 14D, the pixel defining film 401 is formed on a side of the circuit layer 12 away from the base substrate 11. The pixel defining film 401 may be at the same height as the connection portions 30, or may cover the connection portions 30 and the cathode layer 23. The material of the pixel defining film 401 may refer to the material of the pixel defining layer as described above, and details are not repeated here.

In S5, an initial isolation layer 501 is formed.

FIG. 14E is a structural diagram of an initial isolation layer provided in some embodiments of the present disclosure.

Referring to FIG. 14E, the initial isolation layer 501 is formed on a side of the pixel defining film 401 away from the substrate 10. The initial isolation layer 501 covers the connection portions 30 and the pixel defining film 401. The material of the initial isolation layer 501 may refer to the material of the isolation layer as described above, and details are not repeated here.

In S6, an isolation layer 50 is formed.

FIG. 14F is a structural diagram of an isolation layer provided in some embodiments of the present disclosure.

Referring to FIG. 14F, the initial isolation layer 501 is patterned by photolithography to form a plurality of isolation openings 51, so as to obtain the isolation layer 50. The isolation opening 51 penetrates the initial isolation layer 501, and each isolation opening 51 corresponds to at least one anode 211. The isolation layer 50 covers the connection portions 30.

In S7, a pixel defining layer 40 is formed.

FIG. 14G is a structural diagram of a pixel defining layer provided in some embodiments of the present disclosure.

Referring to FIG. 14G, the pixel defining film 401 is patterned by photolithography to form a plurality of pixel openings 41, so as to obtain the pixel defining layer 40. A portion of the connection portion 30 is exposed by a side face of the pixel opening 41, and the exposed portion of the connection portion 30 is used to connect the cathode formed subsequently to the connection portion 30. The exposed portion of the connection portion 30 may be a first connection column of a first connection portion, a second connection column group of a second connection portion, a first connection sub-portion of the second connection portion, or both the second connection column group and the first connection sub-portion of the second connection portion. A portion of the anode 211 is exposed by a bottom of the pixel opening 41. The plurality of pixel openings 41 include a first pixel opening 411, a second pixel opening 412 and a third pixel opening 413. The first pixel opening 411 corresponds to the first light-emitting sub-layer, the second pixel opening 412 corresponds to the second light-emitting sub-layer, and the third pixel opening 413 corresponds to the third light-emitting sub-layer.

The pixel defining layer 40 further includes a pixel defining main body 42. The isolation layer 50 covers the pixel defining main body 42. For the material and the structure of the pixel defining layer 40, reference may be made to the above description, and details are not repeated here.

In S8, a plurality of light-emitting devices are formed.

The plurality of light-emitting devices include a first light-emitting device, a second light-emitting device and a third light-emitting device. The first light-emitting device includes a cathode, an anode and a first light-emitting sub-layer between the cathode and the anode. The second light-emitting device includes a cathode, an anode and a second light-emitting sub-layer between the cathode and the anode. The third light-emitting device includes a cathode, an anode and a third light-emitting sub-layer between the cathode and the anode. The first light-emitting device is configured to emit red light, the second light-emitting device is configured to emit green light, and the third light-emitting device is configured to emit blue light.

The embodiments of the present disclosure are described by considering an example of first forming the first light-emitting device, then forming the second light-emitting device, and finally forming the third light-emitting device. It can be understood that an order of forming the first light-emitting device, the second light-emitting device and the third light-emitting device may also be other orders, and the embodiments of the present disclosure are not limited thereto.

The process of forming a plurality of light-emitting devices may include steps S81 to S86.

FIGS. 14H to 14M are structural diagrams in steps of forming a plurality of light-emitting devices provided in some embodiments of the present disclosure.

In S81, a first light-emitting layer 202, an initial first cathode layer 203 and an initial first encapsulation layer 601 are formed.

Referring to FIG. 14H, the first light-emitting layer 202, the initial first cathode layer 203 and the initial first encapsulation layer 601 that are stacked are formed sequentially. A portion of the first light-emitting layer 202 is located in a pixel opening 41, and another portion of the first light-emitting layer 202 is located on a side of the isolation layer 50 away from the substrate 10. The initial first cathode layer 203 is located on a side of the first light-emitting layer 202 away from the substrate 10, where a portion of the initial first cathode layer 203 is located within the pixel opening 41. The initial first encapsulation layer 601 is located on a side of the initial first cathode layer 203 away from the substrate 10.

The portion of the first light-emitting layer 202 located in the first pixel opening 411 is a first light-emitting sub-layer 221, a portion of the initial first cathode layer 203 located in the first pixel opening 411 is a cathode 231 corresponding to the first light-emitting sub-layer 221, a portion of the initial first encapsulation layer 601 located on a side of the first light-emitting sub-layer 221 away from the substrate 10 is a first encapsulation sub-layer 611, and the first encapsulation sub-layer 611 covers an isolation opening 51.

In S82, a first light-emitting device L1 is formed.

Referring to FIG. 141, the first light-emitting sub-layer 221, the cathode 231 corresponding to the first light-emitting sub-layer 221, and the first encapsulation sub-layer 611 are retained, and other portions of the first light-emitting layer 202, the initial first cathode layer 203 and the initial first encapsulation layer 601 are removed to expose the second pixel opening 412, the third pixel opening 413, and isolation openings 51 corresponding to the second pixel opening 412 and the third pixel opening 413. The anode 211, the first light-emitting sub-layer 221 and the cathode 231 that are stacked in sequence constitute a first light-emitting device L1.

In S83, a second light-emitting layer 204, an initial second cathode layer 205 and an initial second encapsulation layer 602 are formed.

Referring to FIG. 14J, the second light-emitting layer 204, the initial second cathode layer 205 and the initial second encapsulation layer 602 that are stacked are formed sequentially. A portion of the second light-emitting layer 204 is located on a side of the isolation layer 50 away from the substrate 10, a portion of the second light-emitting layer 204 is located on a side of the first encapsulation sub-layer 611 away from the substrate 10, and another portion of the second light-emitting layer 204 is located in a pixel opening 41. The initial second cathode layer 205 is located on a side of the second light-emitting layer 204 away from the substrate 10, where a portion of the initial second cathode layer 205 is located within the pixel opening 41. The initial second encapsulation layer 602 is located on a side of the initial second cathode layer 205 away from the substrate 10.

The portion of the second light-emitting layer 204 located in the second pixel opening 412 is a second light-emitting sub-layer 222, a portion of the initial second cathode layer 205 located in the second pixel opening 412 is a cathode 231 corresponding to the second light-emitting sub-layer 222, a portion of the initial second encapsulation layer 602 located on a side of the second light-emitting sub-layer 222 away from the substrate 10 is a second encapsulation sub-layer 612, and the second encapsulation sub-layer 612 covers an isolation opening 51.

In S84, a second light-emitting device L2 is formed.

Referring to FIG. 14K, the second light-emitting sub-layer 222, the cathode 231 corresponding to the second light-emitting sub-layer 222, and the second encapsulation sub-layer 612 are retained, and other portions of the second light-emitting layer 204, the initial second cathode layer 205 and the initial second encapsulation layer 602 are removed to expose the third pixel opening 413 and an isolation opening 51 corresponding to the third pixel opening 413. The anode 211, the second light-emitting sub-layer 222 and the cathode 231 that are stacked in sequence constitute a second light-emitting device L2.

In S85, a third light-emitting layer 206, an initial third cathode layer 207 and an initial third encapsulation layer 603 are formed.

Referring to FIG. 14L, the third light-emitting layer 206, the initial third cathode layer 207 and the initial third encapsulation layer 603 that are stacked and formed sequentially. A portion of the third light-emitting layer 206 is located on a side of the isolation layer 50 away from the substrate 10, a portion of the third light-emitting layer 206 is located on a side of the first encapsulation sub-layer 611 away from the substrate 10, a portion of the third light-emitting layer 206 is located on a side of the second encapsulation sub-layer 612 away from the substrate 10, and another portion of the third light-emitting layer 206 is located in a pixel opening 41. The initial third cathode layer 207 is located on a side of the third light-emitting layer 206 away from the substrate 10, where a portion of the initial third cathode layer 207 is located within the third pixel opening 413. The initial third encapsulation layer 603 is located on a side of the initial third cathode layer 207 away from the substrate 10.

The portion of the third light-emitting layer 206 located in the third pixel opening 413 is a third light-emitting sub-layer 223, a portion of the initial third cathode layer 207 located in the third pixel opening 413 is a cathode 231 corresponding to the third light-emitting sub-layer 223, a portion of the initial third encapsulation layer 603 located on a side of the third light-emitting sub-layer 223 away from the substrate 10 is a third encapsulation sub-layer 613, and the third encapsulation sub-layer 613 covers an isolation opening 51 corresponding to the third pixel opening 413.

In S86, a third light-emitting device L3 is formed.

Referring to FIG. 14M, the third light-emitting sub-layer 223, the cathode 231 corresponding to the third light-emitting sub-layer 223, and the third encapsulation sub-layer 613 are retained, and other portions of the third light-emitting layer 206, the initial third cathode layer 207 and the initial third encapsulation layer 603 are removed. The anode 211, the third light-emitting sub-layer 223 and the cathode 231 that are stacked in sequence constitute a third light-emitting device L3. In this case, the first encapsulation sub-layer 611, the second encapsulation sub-layer 612 and the third encapsulation sub-layer 613 form the first inorganic encapsulation layer 61.

In S9, an encapsulation layer 60 is formed.

Referring to FIG. 14N, on a side of the isolation layer 50 and the first inorganic encapsulation layer 61 away from the substrate 10, an organic encapsulation layer 62 is formed by inkjet printing, and a second inorganic encapsulation layer 63 is formed by deposition. For the materials of the first inorganic encapsulation layer 61, the organic encapsulation layer 62 and the second inorganic encapsulation layer 63, reference may be made to the above description, and details are not repeated here. The encapsulation layer with a multi-layer structure may provide multiple protections for the light-emitting device, thereby achieving a good encapsulation effect.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

What is claimed is:

1. A display panel having a plurality of sub-pixels; and
the display panel comprising:
a substrate provided with a circuit layer therein;
a light-emitting device layer disposed on a side of the substrate, the light-emitting device layer including:
a cathode layer and an anode layer that are disposed opposite to each other, wherein the cathode layer is farther away from the substrate than the anode layer; the cathode layer includes a plurality of cathodes separate from one another; and a cathode corresponds to at least one sub-pixel; and
a light-emitting layer disposed between the cathode layer and the anode layer; and
a plurality of connection portions disposed on the side of the substrate, wherein in a direction parallel to a plane where the substrate is located, a connection portion is located on at least one side of the cathode; and the cathode is connected to the circuit layer by the connection portion.

2. The display panel according to claim 1, wherein at least one connection portion in the plurality of connection portions is a first connection portion, and the first connection portion includes:
a first connection column disposed on the side of the substrate, wherein the cathode is connected to the first connection column, and the first connection column is connected to the circuit layer.

3. The display panel according to claim 2, wherein the first connection column includes a first end away from the substrate and a second end proximate to the substrate, and an orthographic projection of the first end on the substrate is located within an orthographic projection of the second end on the substrate.

4. The display panel according to claim 1, wherein at least one connection portion in the plurality of connection portions is a second connection portion, and the second connection portion includes:
a second connection column group including at least one second connection column and disposed on the side of the substrate; and
a first connection sub-portion disposed on a side of the second connection column proximate to the substrate; wherein
the cathode is connected to at least one of the second connection column group and the first connection sub-portion, and the second connection portion is connected to the circuit layer.

5. The display panel according to claim 4, wherein
the second connection column includes a third end away from the substrate and a fourth end proximate to the substrate; and
the cathode is connected to the second connection column group, the second connection column group is connected to the first connection sub-portion, and an orthographic projection of a third end of a second connection column in the second connection column group connected to the cathode on the substrate is located within an orthographic projection of a fourth end thereof on the substrate.

6. The display panel according to claim 4, wherein an orthographic projection of a second connection column closest to the cathode on the substrate is located within an orthographic projection of the first connection sub-portion on the substrate.

7. The display panel according to claim 1, wherein the display panel comprises a plurality of pixels, each pixel includes at least three sub-pixels, and each sub-pixel has a separate cathode; and
the plurality of connection portions include a first connection portion and/or a second connection portion; a connection portion connected to a cathode of at least one sub-pixel is the first connection portion, and/or a connection portion connected to a cathode of at least one sub-pixel is the second connection portion.

8. The display panel according to claim 7, wherein the circuit layer includes a first signal line, a second signal line and a third signal line; and the pixel includes at least a first sub-pixel, a second sub-pixel and a third sub-pixel; and
a connection portion connected to a cathode of the first sub-pixel is connected to the first signal line; a connection portion connected to a cathode of the second sub-pixel is connected to the second signal line; and a connection portion connected to a cathode of the third sub-pixel is connected to the third signal line.

9. The display panel according to claim 8, wherein the anode layer includes a plurality of anodes; the circuit layer further includes a plurality of pixel circuits, and an anode is connected to a pixel circuit; and
the pixel circuit is not in contact with the first signal line, the second signal line and the third signal line.

10. The display panel according to claim 1, further comprising:
an partition portion, wherein in the direction parallel to the plane where the substrate is located, the partition portion and the connection portion are located on a same side of the cathode connected to the connection portion; and an orthographic projection of the partition portion on the substrate does not overlap with the orthographic projection of the connection portion on the substrate.

11. The display panel according to claim 10, wherein a distance between the partition portion and the cathode is greater than or equal to 2 μm.

12. The display panel according to claim 10, wherein two adjacent cathodes in the plurality of cathodes are a first cathode and a second cathode, and in the direction parallel to the plane where the substrate is located, the first cathode is located on a side of the second cathode; and
the connection portion is connected to the first cathode, and the partition portion is connected to the second cathode.

13. The display panel according to claim 1, wherein the light-emitting device laver includes a plurality of light-emitting devices, and a sub-pixel includes a light-emitting device; the display panel further comprises:
a pixel defining layer disposed on the side of the substrate, wherein the pixel defining layer includes:
a plurality of pixel openings, wherein the light-emitting device of the sub-pixel is disposed corresponding to a pixel opening; and
a pixel defining main body, wherein the connection portion penetrates through the pixel defining main body to be connected to the circuit layer.

14. The display panel according to claim 13, further comprising:
an isolation layer disposed on a side of the pixel defining layer away from the substrate, wherein the isolation layer includes a plurality of isolation openings, the plurality of isolation openings correspond to the plurality of pixel openings, and a dimension of an isolation opening is smaller than a dimension of the pixel opening corresponding to the isolation opening.

15. A display apparatus, comprising the display panel according to claim 1.

16. The display panel according to claim 4, wherein
the second connection column includes a third end away from the substrate and a fourth end proximate to the substrate; and
the cathode is connected to the first connection sub-portion, and an orthographic projection of a fourth end of a second connection column on the substrate is located within an orthographic projection of a third end thereof on the substrate.

17. The display panel according to claim 8, wherein the pixel further includes a fourth sub-pixel, and the fourth sub-pixel and one of the first sub-pixel, the second sub-pixel and the third sub-pixel are configured to emit light of a same color; and
a connection portion connected to a cathode of the fourth sub-pixel and a connection portion connected to a cathode of the sub-pixel configured to emit light of the same color as the fourth sub-pixel are connected to a same signal line.

18. The display panel according to claim 8, wherein in a same pixel, sub-pixels for emitting lights of different colors are connected to different signal lines; and/or in different pixels, sub-pixels for emitting light of a same color are connected to a same signal line.

19. The display panel according to claim 13, wherein the anode layer includes a plurality of anodes, the light-emitting layer includes a plurality of light-emitting sub-layers, and the light-emitting device includes the cathode and an anode, and a light-emitting sub-layer located between the cathode and the anode; and
the plurality of sub-pixels include a red sub-pixel, a green sub-pixel and a blue sub-pixel; and an area of an orthographic projection of a light-emitting sub-layer of the blue sub-pixel on the substrate is greater than an area of an orthographic projection of a light-emitting sub-layer of the red sub-pixel on the substrate and an area of an orthographic projection of a light-emitting sub-layer of the green sub-pixel on the substrate.

20. The display panel according to claim 1, wherein the cathode corresponds to a single sub-pixel; or the cathode corresponds to multiple sub-pixels for emitting light of a same color.
